(19) United States
(12) Patent Application Publication
(10) Pub. No.: US 2014/0022431 A1
(43) Pub. Date: Jan. 23, 2014

(54) CMOS IMAGE SENSOR

(71) Applicant: NANYANG INNOVATION & ENTERPRISE OFFICE, Singapore (SG)

(72) Inventors: Shoushun CHEN, Singapore (SG); Kay Soon Low, Singapore (SG); Xinyuan Qian, Singapore (SG)

(73) Assignee: NANYANG INNOVATION & ENTERPRISE OFFICE, Singapore (SG)

(21) Appl. No.: 13/946,567

(22) Filed: Jul. 19, 2013

Related U.S. Application Data
(60) Provisional application No. 61/673,569, filed on Jul. 19, 2012.

(51) Int. Cl. H01L 27/146; H04N 5/374

(52) U.S. Cl. CPC H01L 27/14643; H04N 5/374
USPC 348/308; 250/208.1

(57) ABSTRACT

A CMOS image sensor comprising: an array of pixels for converting incident light to electrical output signals; interface circuitry configured to connect to the array and configured to: determine whether, and when, the output signal generated by each pixel meets one or more readout thresholds; and read out the output signals from the pixels that have met the one or more readout thresholds.

### CROSS-REFERENCE TO RELATED APPLICATIONS

This application claims the benefit of U.S. Provisional Patent Application No. 61/673,569, filed Jul. 19, 2012 and entitled “A High Dynamic Range CMOS Image Sensor System with Adaptive Integration Time and Multiple Readout Channels”, the contents of which are hereby incorporated by reference in their entirety.

### TECHNICAL FIELD

The present invention relates to a CMOS image sensor.

### BACKGROUND

Imaging scenes usually exhibit a huge variation of illumination depending on the ambient light conditions. Ranging from 10⁻³ lux under dark conditions up to 10⁵ lux in bright conditions, the illumination of a scene can accordingly result in illuminance variation of over 100 dB.

The capability of an image sensor to accurately capture both dark and bright areas in a single scene is defined as intra-scene dynamic range (DR). From the image sensor's perspective, the dynamic range can be defined as the log-ratio of the largest non-saturating signal under bright conditions to the smallest detectable signal under dark conditions. Although CMOS image sensors have improved significantly recently in terms of reducing readout noise, thereby enhancing the detection of small signals under dark conditions, they are still typically only capable of capturing around 70 dB DR with pixels operating in the conventional photocurrent integration mode.

A number of approaches to achieve high dynamic range (HDR) in CMOS image sensors have been proposed.

A first approach is to realize a nonlinear pixel response (e.g., a logarithmic response) to compress the photocurrent-voltage transfer characteristics. Disadvantages of this approach include low signal to noise ratio (SNR) in low light conditions, and large fixed pattern noise.

An alternative approach is to use multiple sampling, also known as multiple capture. Multiple sampling extends the DR by capturing the image multiple times with different exposure times. The multiple captured samples are synthesized during image reconstruction, for example by calculating a weighted average of the samples. A problem with this approach is that there will be a SNR dip between successive samples, lowering the SNR of the synthesized image.

A third proposed approach is often termed as time-to-saturation (TTS). This approach basically allows the pixel to achieve its saturation level, and extrapolates the measured signal to infer the impinging light intensity by measuring the time required to reach the saturation state.

CMOS image sensors which incorporate the dimension of time as a system variable in this way are commonly referred to as time-domain imagers. Most time-domain imagers need to include a pixel-level comparison and memory component. This results in huge complexity, lower fill factor and increased pixel area, making time-domain imagers generally impractical for high-resolution imaging applications.

### SUMMARY

In general terms the invention proposes an off array or off chip readout circuitry, which reads out the voltage of each pixel only once it enters a threshold window. The pixel current may then be reconstructed using the readout time. The may allow a significantly improved dynamic range without increasing the chip or array size.

In a first specific expression of the invention there is provided a CMOS image sensor comprising:
an array of pixels for converting incident light to electrical output signals; and
interface circuitry configured to connect to the array and configured to:
   determine whether, and when, the output signal generated by each pixel meets one or more readout thresholds; and
   read out the output signals from the pixels that have met the one or more readout thresholds.
The interface circuitry may be separate from the array of pixels.
The readout thresholds may comprise an upper voltage threshold and a lower voltage threshold defining a readout window.
The interface circuitry may be further configured to identify pixels which have been read out, wherein identified pixels are not read out again during a predetermined exposure period.
The identified pixels may be disabled following readout, for example by setting their voltages to values which do not meet the readout thresholds.
The interface circuitry may be configured to simultaneously sample output signals from a plurality of pixels. The plurality of pixels may be a row of pixels.
A plurality of readout channels may provide readout of output signals from the pixels that have met the one or more readout thresholds. The interface circuitry may comprise an assignment logic for assigning said output signals to the readout channels.
The interface circuitry may comprise high dynamic range (HDR) detection circuitry for determining, for each of the plurality of pixels at the same time, whether ones of said plurality of pixels meet the one or more readout thresholds. The HDR detection circuitry may be separate from the array of pixels.

In a second specific expression of the invention there is provided a CMOS image sensor, comprising:
an array of pixels arranged in rows and columns, each said pixel including a photo-detection element for converting incident light to an electrical output signal; and
exposure control circuitry operatively coupled to the array and being configured to determine an exposure time for each pixel, and measuring the output of each pixel at or after the respective exposure time.

In a third specific expression of the invention there is provided a high dynamic range image capture method at least partly performed by a CMOS image sensor comprising an array of pixels, the method comprising:
determining whether, and when, the output signal generated by each pixel meets one or more readout thresholds; and
reading out the output signals from the pixels that have met the one or more readout thresholds.
Wherein pixels which have been read out may be identified, wherein the identified pixels are not read out again during a predetermined exposure period. The identified pixels may be disabled following readout. The disabling may comprise setting voltages of the identified pixels to values which do not meet the readout thresholds.
The determining may comprise simultaneously sampling output signals from a plurality of pixels. The plurality of pixels may be a row of pixels.
For each of the plurality of pixels, it may be determined at the same time, whether ones of said plurality of pixels meet the one or more readout thresholds.
Each of a plurality of readout channels, may be assigned an output signal from the pixels that have met the one or more readout thresholds.
Photocurrents from the output signals may be calculated.
An image may be reconstructed from the photocurrents.

In a forth specific expression of the invention there is provided an image sensor system, comprising:
(a) an array of pixel elements arranged in a plurality of row lines and column lines;
(b) a row selector to get access to a row of pixel elements at a time;
(c) a column-parallel HDR detection circuit connected in parallel to the plurality of column lines;
(d) multiple readout channels to provide sufficient readout bandwidth;
(e) an assignment logic build block to manage multiple readout channels and communication with HDR detection circuits, comprising logic for:
   (i) a channel availability check and
   (ii) a channel assignment operation; and
(f) a global timer to record times when the rows of pixels are sampled.

In a firth specific expression of the invention there is provided a method for capturing HDR images using an image sensor system comprising a pixel array, the method comprising:
(a) globally resetting the pixel array and initiating an exposure to snapshot an imaging scene;
(b) generating electrical signals from incident light with the pixel array in a plurality of row lines and column lines at the same time;
(c) immediately after the exposure begins, starting a row-wise scanning operation and selecting rows of pixel elements sequentially from the top of the pixel array;
(d) when a row is selected, determining, by a column-parallel voltage check operation, whether the pixel voltages in the row can be readout;
(e) assigning, in a channel assignment operation, the row of pixels to a readout channel for readout;
(f) immediately on completion of the channel assignment operation, continuing row-wise scanning, selecting the next row and repeating step (d);
(g) when the last row is scanned, checked and assigned according to steps (d) and (e), finishing a round of row-wise scanning and commencing a subsequent round of row-wise scanning by repeating step (c); and
(h) stopping the scanning when the time exceeds the exposure limit at the end of a scanning round, thereby finishing capture of the imaging scene.

In accordance with embodiments, an image capture method in a CMOS image sensor wherein a two-dimensional array of pixel elements is used as a photo-detection apparatus is described. The method summarizes a single-exposure snapshot capture of the scene, during which, an off-array column-parallel HDR detection circuitry repetitively measures and examines the analog values of the pixel elements in the manner of row-wise scanning. When examining a row of pixels, the analog pixel values are compared with two reference voltages, the reference voltages defining a feasible pixel readout window to determine whether the pixel has reached the readout threshold or not. A digital readout indicator is used to carry this information for each pixel when analog pixel values fall within the readout window.

In certain embodiments, there is an assignment operation after the examining operation. The row of pixels may be assigned to an analog readout channel for analog output and the indicators in each column as described may be used as a feedback control signal back to the pixel, the combination of which with a row select (RSL) signal thereby indicates the exact coordinates of the pixel that has been read out. Meanwhile, in company with the analog output, the temporal information of each pixel may be provided by the global time counter, the pixel output signal and timing information later being useful in post-processing to reconstruct photocurrent information for each pixel.

According to certain embodiments, the sensor may include multiple analog readout channels to provide increased readout bandwidth and to accelerate the speed of row-wise scanning. In certain embodiments, the row-wise scanning will not switch to the next row to examine it until the analog values of the currently examined row are assigned to a free readout channel. The availability of free channels during row-wise scanning may influence the assignment speed. An assignment logic component may manage the availability and priority of the channels as well as synchronizing and communicating with HDR detection circuitry for the assignment operation.

Certain embodiments provide programmable reference voltage thresholds. Advantageously in these embodiments, the readout window can be tuned by modifying an upper threshold and/or a lower threshold in order to modify the size and/or position of the readout window. For pixels with large photocurrent the voltage value soon falls into the readout window, resulting in an early readout. On the other hand, if a pixel has small photocurrent, the pixel signal will experience a much longer exposure time before it reaches the readout threshold so as to achieve acceptable signal-to-noise ratio (SNR) compared to fixed exposure mode.

In certain embodiments, the interface circuitry includes high dynamic range (HDR) detection circuitry. The HDR detection circuitry may be separate from the pixel array. Advantageously, by providing the HDR detection circuitry separately to the pixel array, embodiments may execute all the HDR operations of measuring, comparison, and control outside of the pixel, thereby tremendously decreasing the pixel transistor count and leaving the majority of the pixel area for the photo-detection device. This architecture enables the use of small-sized Active Pixel Sensor (APS)-like pixels with high fill factor that facilitates the production of high dynamic range CMOS image sensors having very high resolution.

### BRIEF DESCRIPTION OF THE DRAWINGS

Embodiments of the invention will now be described, by way of non-limiting example only, with reference to the accompanying drawings in which:

FIG. 1 is a simplified block diagram illustrating a CMOS image sensor according to embodiments of the present invention, suitable for performing a high dynamic range image capture method of embodiments of the invention;

FIG. 2 is a simplified block diagram showing the arrangement of pixel elements in the pixel array of the CMOS image sensor of FIG. 1, and illustrating signal communications between the pixel array and other components;

FIG. 3 is a simplified block diagram showing a pixel element according to certain embodiments;

FIG. 4 is a simplified block diagram of column-parallel HDR detection circuitry suitable for use with the image sensor of FIG. 1;

FIG. 5 is a simplified block diagram of multiple readout channels and assignment logic for the image sensor of FIG. 1;

FIGS. 6(A) and 6(B) are flowcharts showing a high dynamic range image capture method according to embodiments of the present invention; and

FIG. 7 illustrates a typical pixel voltage response curve for exemplary pixels in photocurrent integration mode, and shows how a combination of readout time and analog voltage can be used to reconstruct the photocurrent.

### DETAILED DESCRIPTION

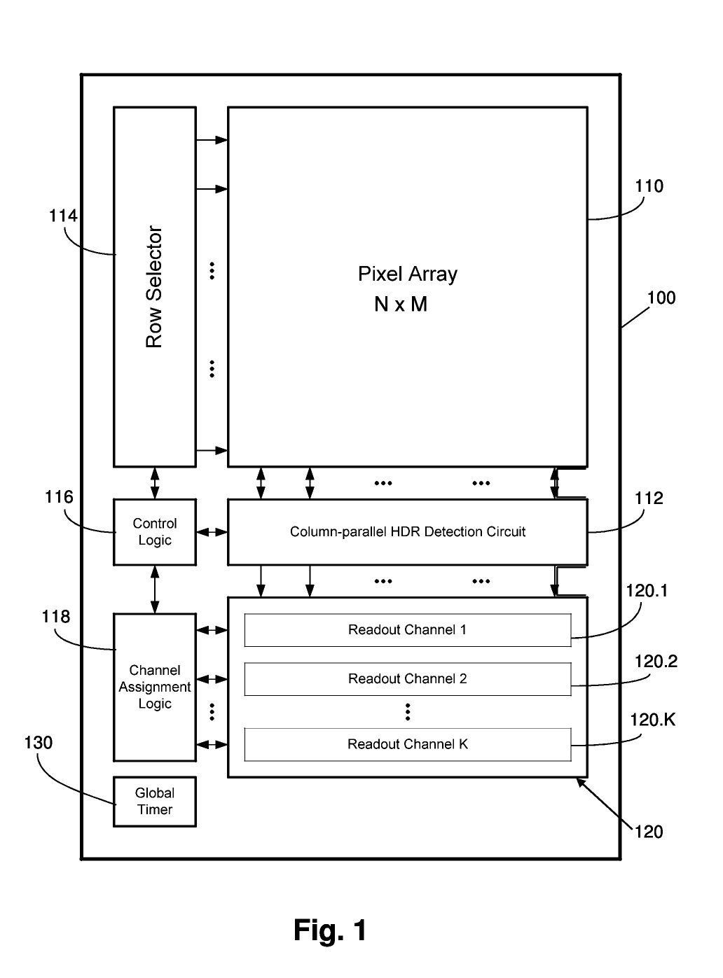

FIG. 1 is a simplified block diagram illustrating a CMOS image sensor system 100 suitable for performing a HDR image capture method in accordance with certain embodiments of the present invention.

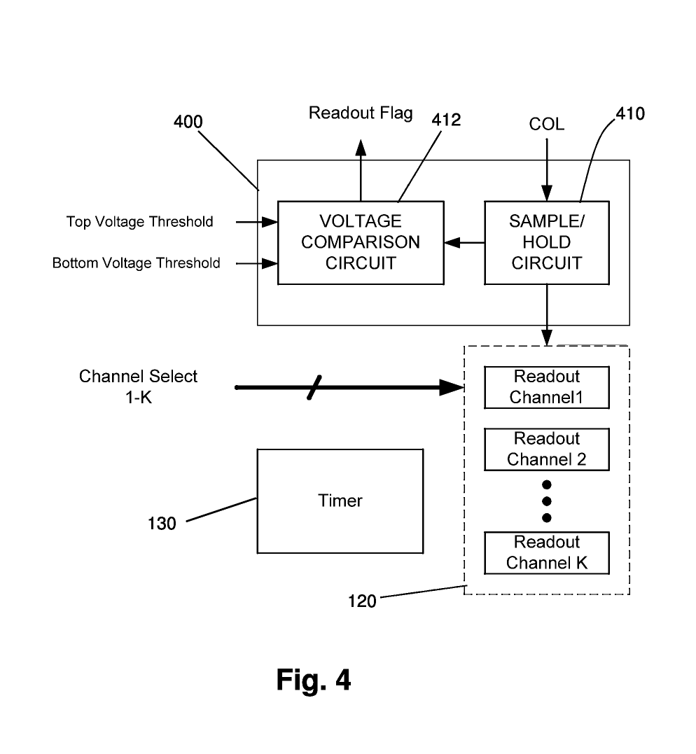

CMOS image sensor 100 includes a pixel array 110 comprising pixel elements arranged in N rows and M columns. Separate from the array 110, and configured to connect to the array 110, is off-array interface circuitry comprising a number of functional components as will be described in detail below. The interface circuitry includes a row selector 114, which sends a signal to the pixel array 110 to select a specific row of pixels. An HDR detection circuit 112 comprising M column-parallel HDR detection circuit units (FIG. 4), one for each column of the pixel array 110, is aligned with the pixel array 110 column-by-column and is coupled to the pixels through two column buses per column as will be later described.

Readout channels 120 are coupled to the column-parallel HDR detection circuit 112 to receive pixel voltages therefrom. There are K readout channels (120.1, 120.2, . . . , 120.K) to provide increased readout bandwidth relative to known single-channel readout. A channel assignment logic 118 monitors the statuses of the K readout channels and manages assignment of sampled signals from the pixel array 110 to the readout channels. It will be appreciated that the number K of readout channels can be chosen as large as is feasible for any size constraints for the image sensor 100 (noting that larger K means greater readout bandwidth and hence greater readout speed), and/or based on the number of rows N in the pixel array 110, the number of columns M, the channel readout speed, or other parameters of the image sensor 100 and/or the type of scene to be imaged with the sensor 100.

Control logic circuitry 116 generates control signals for accessing, controlling and processing signals among the respective building blocks 112, 114 and 118. As will be described in greater detail later, control logic 116 is configured to communicate with and to control HDR detection circuit 112, row selector 114 and assignment logic 118 to scan through the pixel array 110 in row-wise fashion, to determine whether pixel signals in respective rows meet one or more HDR readout criteria (e.g., whether a measured pixel quantity such as pixel voltage falls within a readout window), to read out pixel signals meeting the criteria, and to repeat the row-wise scanning until a predetermined exposure time is reached.

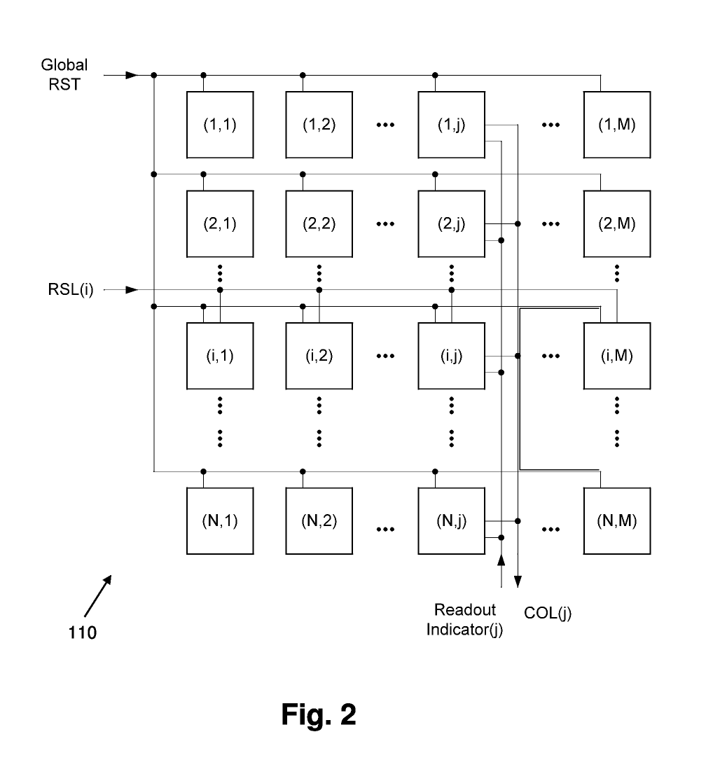

FIG. 2 is a simplified block diagram showing the arrangement of pixel elements in the pixel array 110 and schematically depicting signal communications with other components. The pixel elements are arranged in an array of N rows and M columns.

Global RST is a pixel reset signal that resets a pixel to its initial state. It is globally shared by all pixel elements in the pixel array 110. The array 110 can accordingly be operated in a global shutter mode, wherein the pixels are reset at the same time.

Control signal RSL(i), received from row selector 114, selects the i^{th} row of pixels, and is supplied in a horizontal direction. Each column j is connected to two vertical (column) buses COL(j) and Readout Indicator(j). Column bus COL(j) outputs the analog pixel voltage on the j^{th} column and Readout Indicator(j) is the feedback control signal for the j^{th} column. Column bus COL(j) and Readout Indicator(j) are both connected to, and communicate with, an HDR detection circuit unit (of HDR detection circuit 112) for a specific column, as will be described in detail later. Both column buses COL(j) and Readout Indicator(j) will be dedicated to a specific pixel element (i,j) when RSL(i) is sent to the array 110 at any given time to thereby select the i^{th} row. Therefore, from the perspective of the entire pixel array 110, the integrated charges in respective pixels are read out in column-parallel and one row at a time.

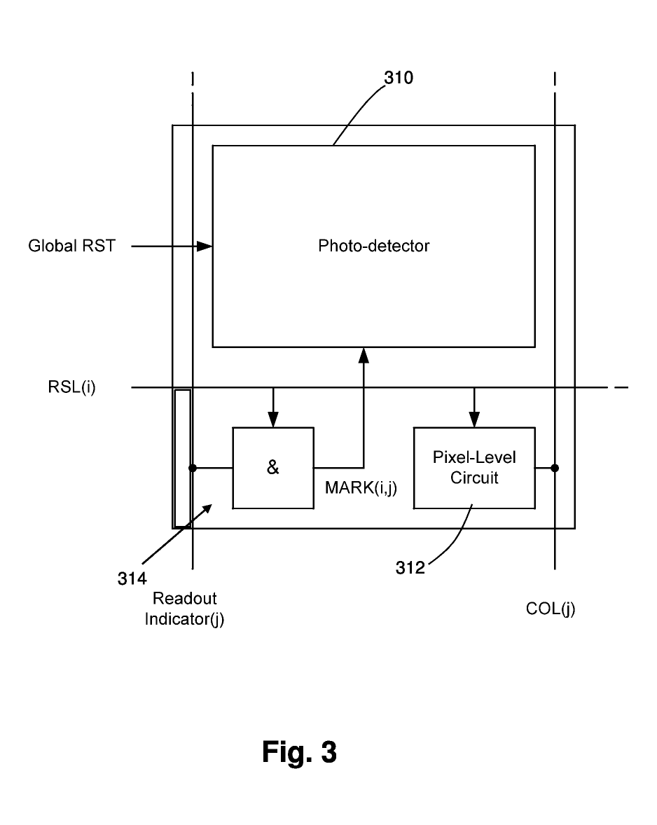

Further details of a pixel element are illustrated in FIG. 3. The pixel element includes a photo-detector 310, pixel-level circuit 312 as typically provided in known CMOS pixel sensors, and a feedback circuit (generally indicated at 314). The photo-detector 310 may have a capacitance and may work in integration mode, whereby incident light received at photo-detector 310 discharges the capacitance, generating a pixel output signal in the form of a voltage. Photo-detector 310 may be a photo-gate, a photodiode, a phototransistor, or any other device that converts incident light into electric charge.

The pixel-level circuit 312 takes signal RSL(i) as an input. This grants the output signal of the pixel access to the column bus COL(j). Pixel-level circuit 312 may in addition include an amplifier (not shown) to amplify the accumulated charges on the photo-detector. In exemplary embodiments the pixel-level circuit 312 may comprise a three-transistor circuit as in an active pixel sensor, such that the photo-detector 310 is followed by a reset transistor, a source follower transistor as a voltage buffer, and a row select transistor which receives signal RSL(i) to enable the column access function.

Readout Indicator(j) is a feedback indicator generated from the j^{th} HDR detection circuit unit of HDR detection circuit 112, as will be explained later. In the scan (row-wise voltage checking procedure) of the array, when row i is selected and it has been determined that pixel (i,j) should be read out, according to a comparison between the pixel voltage and a pre-defined (and programmable) readout window, Readout Indicator(j) flags pixel (i,j) as having been read.

Readout Indicator(j) is column-shared. The AND operation performed in the feedback circuit 314 prevents the feedback signal from influencing other pixels, and only allows it to flag the exact row-selected pixel. The generated MARK(i,j) signal may flag/disable the pixel by means of, for example, pulling down the pixel voltage, resetting the pixel voltage to its initial value, or by performing another operation that allows the HDR detection circuit 112 to recognize that the pixel (i,j) has already been read out. This avoids the possibility of a mistaken double readout of a single pixel in consecutive row-wise voltage checks (scans).

The column-parallel HDR detection circuit 112 in FIG. 1 comprises a plurality of HDR detection circuit units, one for each column of the pixel array 110. A more detailed view of one of the M HDR detection circuit units 400 is shown in FIG. 4. The M column-parallel units 400 are substantially identical to each other.

For each column, a Sample/Hold circuit 410 of HDR detection circuit unit 400 non-destructively samples and stores the pixel voltage received from column bus COL. The global timer 130 records the time at which the pixel was sampled. A comparison circuit 412 compares the sampled voltage with a top voltage threshold and a bottom voltage threshold. The top and bottom voltage thresholds define a readout window. The top (upper) threshold defines a threshold that the pixel needs to discharge below before it is read out. The bottom (lower) threshold is a saturation threshold, i.e. the pixel should not be read out if it is saturated. When the pixel voltage is lower than the top voltage threshold and higher than the bottom voltage threshold, i.e. it falls into the readout window, the pixel is ready for readout and the corresponding Readout Flag is set.

After the comparison performed by comparison circuit 412, the pixel voltage is then assigned to one of the K readout channels 120. From the perspective of the HDR detection circuit 112, a row is assigned due to the row-wise pixel voltage check operation. When the comparison process has been completed for a row as discussed above, some or all of the columns in the row may need readout. When the row is assigned to a readout channel, the channel is also configured by the readout flags. One possible architecture of the readout channel is to use these flags to configure the length of the readout chain so that it skips the columns where the pixel does not meet the readout criterion. As will be appreciated by the skilled person, many other readout channel architectures are possible.

The selection of a specific readout channel is performed by the Assignment Logic 118. Assignment Logic 118 sends a Channel Select signal to each readout channel to indicate whether respective channels have been selected for readout. Only one channel can be selected at one time, that is, each pixel voltage in the row can only be assigned to one readout channel at a given time, for example, readout channel K.

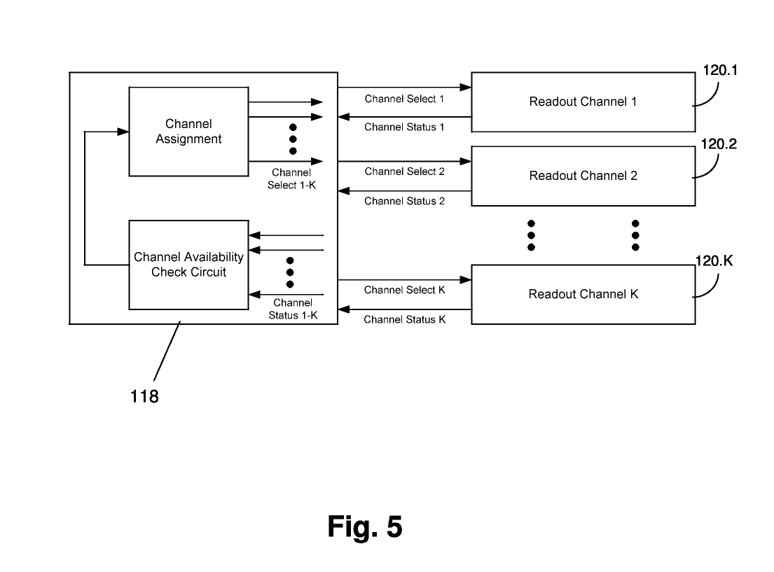

The Assignment Logic 118 and its relationship to, and communication with, Readout Channels (120.1, 120.2, . . . , 120.K) are further illustrated in FIG. 5. The readout channels 120 operate independently of each other but are uniformly managed by Assignment Logic 118 to avoid conflicts. Assignment Logic 118 receives channel statuses from each of the readout channels 120. The channel status can be either “busy” or “free”, respectively indicating that the channel is either currently reading out a row or that it is available for readout.

When a row is required to be assigned, Assignment Logic 118 will accumulate the channel statuses, and find a “free” channel to which the row is to be assigned. In the event that no channel is available, the Assignment Logic 118 will wait until one of the “busy” channels finishes readout and becomes free. If there are multiple available channels, a “top priority”-based channel assignment logic may be implemented. In this configuration, each channel is initially assigned a priority number, and Assignment Logic 118 will assign to the channel with the highest priority amongst the available channels. Each channel is assigned a priority number beforehand. The simplest and most preferable is a linear priority sequence, that is, highest priority for channel 1, reducing to lowest priority for channel K, or vice versa. A variety of other algorithms for the assignment logic may be employed as long as one free channel is enabled for assignment at a time.

Each readout channel of the readout channels 120 functions to read out pixel voltages in one form or another. The architecture of the readout channels may vary widely as will be appreciated by those skilled in the art. For example, a readout channel may employ a selective readout scan chain, wherein the voltage shifts out selectively depending on which column is ready for readout. Alternatively, an asynchronous readout scheme such as Address Event Representation (AER) may be used. The readout channel may further include a column-parallel Analog to Digital Converter (ADC) (not shown), which converts analog voltages into digital form for further processing.

The operation of an HDR image capture method of embodiments of the present invention will now be described. The image capture method, in embodiments, may be (but need not be) implemented in the CMOS image sensor 100 of FIG. 1 to FIG. 5.

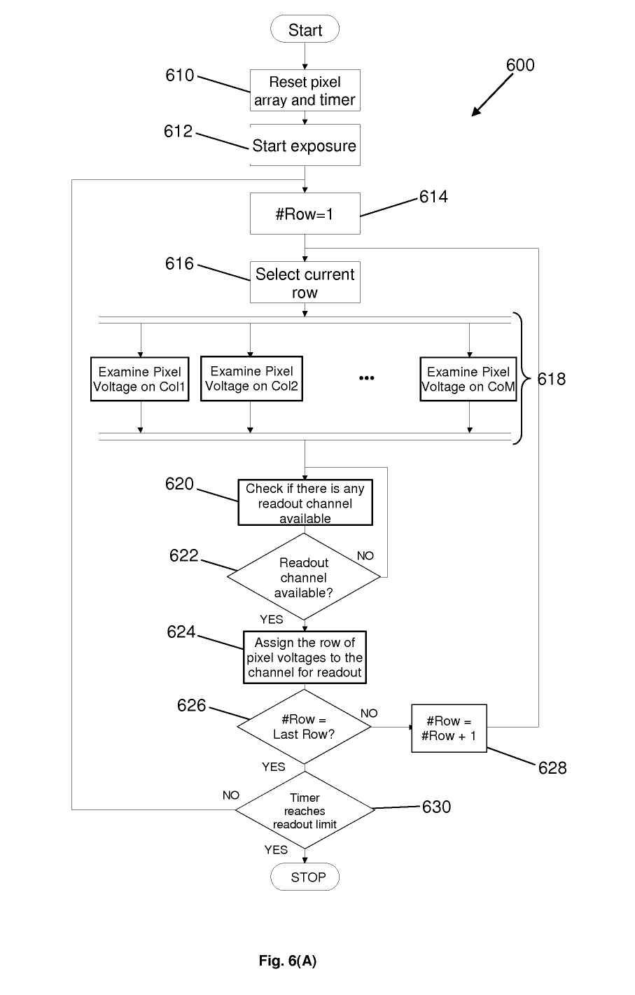

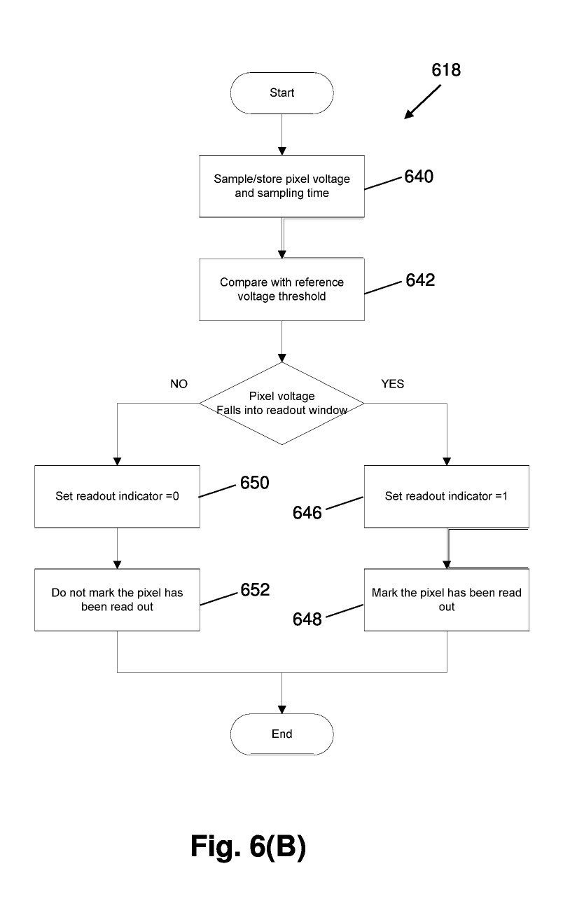

FIG. 6(A) and FIG. 6(B) are flowcharts illustrating an image capture method 600 according to certain embodiments of the present invention. The overall flow of process 600 is controlled by control logic 116 with assignment logic 118, with which control logic 116 communicates, as a co-controller for monitoring and managing the multiple readout channels. Control logic 116 orchestrates the sensor components to perform their various functions as described herein.

As shown in FIG. 6(A), at the commencement of an image capture process, the pixel elements in the pixel array 110 are reset at block 610 to an initial state, such as Vrst. Vrst is the voltage on the photo-detector after a global reset. The global timer 130 is also cleared. A snapshot of an imaging scene starts at block 612 by exposing the pixel array 110 to the imaging scene. As soon as the pixel array 110 starts integrating photocurrent, a row-wise scanning and voltage check process is commenced in order to perform HDR detection.

The process 600 initializes the row number to one at block 614. Row selector 114 then selects the first row of pixel elements (block 616). The pixel voltages on this row (which has M columns) are then examined, at the same time, by a column-parallel detection process 618 executed by HDR detection circuit 112.

The column-parallel detection process 618 is shown in further detail in FIG. 6(B). Although the process is specifically illustrated for only one column, it will be understood that a similar process is performed simultaneously for each of the M pixels in the selected row. At block 640, the pixel voltage is sampled and stored, by one of the HDR detection circuit units 400, in the SAMPLE/HOLD circuit 410 via the column bus COL (FIG. 4). The time of the sampling operation (as registered by global timer 130) is also recorded. At block 640, the sampled voltage is sent to the comparison circuit for voltage comparison (block 644). If the pixel voltage falls into the readout window (between the top voltage threshold and bottom voltage threshold as previously described), the readout indicator for this pixel is set equal to 1 (block 646), indicating that the pixel can be read out. Otherwise, the readout indicator is reset equal to 0 (block 650). If the readout indicator is set to 1 then the pixel is marked as having been read out (block 648), otherwise it is marked as not having been read out (block 652).

Referring back to FIG. 6(A), the column-parallel process 618 illustrated in part in FIG. 6(B) is synchronized so that the readout indicators for a row are either set or reset for all columns after the examining process 618, and the pixel voltages are ready for readout. As alluded to above, the selected row should be assigned to a readout channel. This is done according to a channel assignment process. Assignment Logic 118 checks at block 620 whether there is any readout channel available. If not, the process loops back from block 622 to block 620. Once there are available channels, the assignment takes place, and the row of pixel voltages is copied to the selected readout channel (block 624). Since the readout channel operates independently of the row-wise scanning part of the process 600, and only reports its status to the Assignment Logic 118, the row-wise scanning can continue without the information in the readout channel. Therefore, the row-wise scanning continues as soon as the selected row of pixels has been assigned to a readout channel. Control logic 116 first checks, at block 626, whether the last row has been reached. If not, the row count is incremented (block 628) and the process 600 loops back to block 616 to scan the next row, and repeat the aforementioned column-parallel examining process and channel assignment process. If the last row is reached, the current round of row-wise scanning is concluded. Control logic 116 then checks, at block 630, whether a predefined exposure time limit has been reached. If not, the process returns to block 614, and the previously-described row-wise scanning process is repeated, starting again from the first row. This iterative process continues until the timer reaches the predefined exposure limit. Advantageously, the process 600 involves a single exposure of the imaging scene, and requires only a single global reset of the pixel array 110. Accordingly, the presently described device architecture and process do not suffer from the SNR dip experienced with multiple sampling methods.

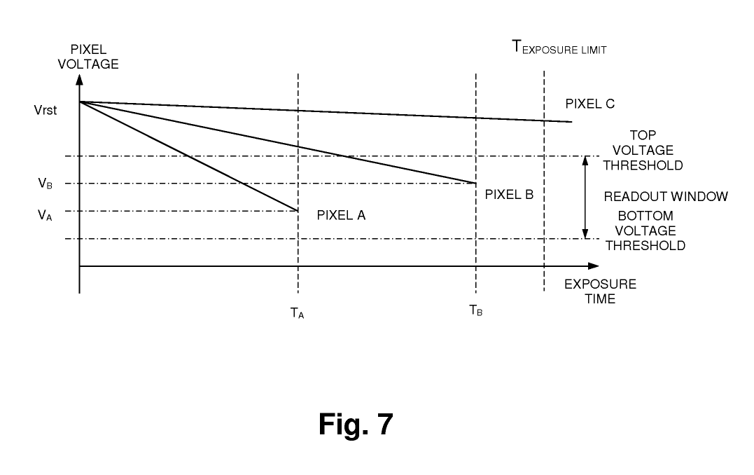

FIG. 7 illustrates the pixel voltage response vs. exposure time curve for representative pixels A, B, C under varying incident illumination. Pixel A experiences a sharp discharge rate from the initial level of Vᵣₛₜ (the reset voltage on the photo-detector after a global reset), denoting a large photocurrent, which in turn corresponds to a strong incident light intensity. Pixel B generates a moderate photocurrent. Pixel C has a small discharge rate and can be considered to be under dark conditions. It will be appreciated that these pixels can reside anywhere in the pixel array.

In the image capture process illustrated in FIG. 6(A) and FIG. 6(B), the row-wise scanning and row-wise voltage check start from the first row immediately after the pixel array 110 is reset, i.e. row-wise scanning starts when integration starts. Bright pixel A resides in a row which is scanned at time T_{A}. At T_{A}, the row-wise scanning examines the entire row where pixel A resides, and the pixel voltage V_{A} of pixel A is sampled together with other pixels on the same row. Voltage V_{A} (and each of the other voltages in the same row) is compared with the top and bottom voltage thresholds as previously described. Clearly, it falls within the readout window and is ready for readout. Therefore, the sampling time T_{A} is recorded and the pixel voltage V_{A} is assigned to one of the readout channels (by Assignment Logic 118).

According to embodiments of the present invention, both the sampling time and the pixel voltage can be utilized to reconstruct the pixel photocurrent, thereby allowing reconstruction of HDR images. The photocurrent of pixel A can be expressed In Equation 1:

$${Iph}_{A} = \frac{{C}_{PD} ( {V}_{rst} - {V}_{A} )}{{T}_{A}} \qquad ( 1 )$$

where C_{PD} is the parasitic capacitance on the photo-detector of pixel A.

As can be seen from FIG. 7, at time T_{A} when pixel A is read out, the voltage of pixel B is higher than the top voltage threshold, i.e. it falls outside the readout window and so is not read out. However, in a subsequent round of row-wise scanning, at time T_{B}, it has discharged sufficiently to fall to a voltage V_{B} which is within the readout window. The photocurrent of pixel B (which experiences moderate light intensity) can then be expressed in Equation 2:

$${Iph}_{B} = \frac{{C}_{PD} ( {V}_{rst} - {V}_{B} )}{{T}_{B}} \qquad ( 2 )$$

As for pixel C in low light intensity, the pixel voltage does not fall into the readout window by the time that the global timer 130 reaches the predefined exposure limit, T_{exposure limit}. Therefore, pixel C is considered to be a dark pixel. During the image reconstruction process, its photocurrent will be treated as zero due to never having been read out.

In certain embodiments, either or both of T_{exposure limit} and the readout window may be programmable. Advantageously, this allows flexibility in defining different thresholds and exposure times, possibly in adaptive fashion. For example, the ambient light intensity could be measured by some other apparatus which is in communication with image sensor 100. The measured illumination information may then be conveyed to control logic 116, allowing it to modify the exposure time limit and/or the thresholds for the readout window.

Once photocurrents for the respective pixels have been calculated as above, they can be normalized and converted to pixel values for image construction and display. For example, one can define a common exposure time for all pixels after photocurrent calculation, then all pixel values can be calculated by multiplying their photocurrents by the common exposure time.

It should be noted that the time scale in FIG. 7 is exaggerated. For example, T_{A} can be small, while T_{exposure limit} can be very long.

In the method described with reference to FIG. 6(A), the sequential row-wise nature of the scanning process means that the time it takes to reach the row where pixel A resides depends on the location of the row in the pixel array. The time can include the time spent on sample/hold and comparison by HDR detection circuit 112, and the time spent on assignment of each row by Assignment Logic 118. On the other hand, as long as the HDR detection circuit 112 determines that the pixel voltage is in the readout window, it triggers readout of the corresponding pixel. It may also take several rounds of row-wise scanning until the voltage for a particular pixel falls into the readout window. Taking Pixel B as an example, before T_{B}, there is possibility that Pixel B is scanned and checked several times but not found in the readout window. On the other hand, as long as T_{B} is below T_{exposure limit}, pixel B can be read out.

While example embodiments of the invention have been described in detail, many variations are possible within the scope of the invention as claimed as will be clear to a skilled reader.

1. A CMOS image sensor comprising:
an array of pixels for converting incident light to electrical output signals; and
interface circuitry configured to connect to the array and configured to:
determine whether, and when, the output signal generated by each pixel meets one or more readout thresholds; and
read out the output signals from the pixels that have met the one or more readout thresholds.

2. A CMOS image sensor according to claim 1, wherein the interface circuitry is separate from the array of pixels.

3. A CMOS image sensor according to claim 1, wherein the readout thresholds comprise an upper voltage threshold and a lower voltage threshold defining a readout window.

4. A CMOS image sensor according to claim 1, wherein the interface circuitry is further configured to identify pixels which have been read out, and wherein identified pixels are not read out again during a predetermined exposure period.

5. A CMOS image sensor according to claim 4, wherein the identified pixels are disabled following readout.

6. A CMOS image sensor according to claim 5, wherein the identified pixels are disabled by setting their voltages to values which do not meet the readout thresholds.

7. A CMOS image sensor according to claim 1, wherein the interface circuitry is configured to simultaneously sample output signals from a plurality of pixels.

8. A CMOS image sensor according to claim 7, wherein the plurality of pixels is a row of pixels.

9. A CMOS image sensor according to claim 1, comprising a plurality of readout channels for readout of output signals from the pixels that have met the one or more readout thresholds.

10. A CMOS image sensor according to claim 9, wherein the interface circuitry comprises an assignment logic for assigning said output signals to the readout channels.

11. A CMOS image sensor according to claim 7, wherein the interface circuitry comprises high dynamic range (HDR) detection circuitry for determining, for each of the plurality of pixels at the same time, whether ones of said plurality of pixels meet the one or more readout thresholds.

12. A CMOS image sensor according to claim 11, wherein the HDR detection circuitry is separate from the array of pixels.

13. A CMOS image sensor, comprising:
an array of pixels arranged in rows and columns, each said pixel including a photo-detection element for converting incident light to an electrical output signal; and
exposure control circuitry operatively coupled to the array and being configured to determine an exposure time for each pixel, and measuring the output of each pixel at or after the respective exposure time.

14. A high dynamic range image capture method at least partly performed by a CMOS image sensor comprising an array of pixels, the method comprising:
determining whether, and when, the output signal generated by each pixel meets one or more readout thresholds; and
reading out the output signals from the pixels that have met the one or more readout thresholds.

15. A method according to claim 13, further comprising identifying pixels which have been read out, wherein the identified pixels are not read out again during a predetermined exposure period.

16. A method according to claim 14, comprising disabling the identified pixels following readout.

17. A method according to claim 15, wherein the disabling comprises setting voltages of the identified pixels to values which do not meet the readout thresholds.

18. A method according to claim 13, wherein the determining comprises simultaneously sampling output signals from a plurality of pixels.

19. A method according to claim 17, wherein the plurality of pixels is a row of pixels.

20. A method according to claim 13, comprising assigning, to each of a plurality of readout channels, an output signal from the pixels that have met the one or more readout thresholds.

21. A method according to claim 17, comprising determining, for each of the plurality of pixels at the same time, whether ones of the plurality of pixels meet the one or more readout thresholds.

22. A method according to claim 13, further comprising calculating photocurrents from the output signals.

23. A method according to claim 21, further comprising reconstructing an image from the photocurrents.

24. A method according to claim 13, wherein said determining and said reading out are performed by high dynamic range (HDR) circuitry which is separate from the array.

25. An image sensor system, comprising:
(a) an array of pixel elements arranged in a plurality of row lines and column lines;
(b) a row selector to get access to a row of pixel elements at a time;
(c) a column-parallel HDR detection circuit connected in parallel to the plurality of column lines;
(d) multiple readout channels to provide sufficient readout bandwidth;
(e) an assignment logic build block to manage multiple readout channels and communication with HDR detection circuits, comprising logic for:
(i) a channel availability check and
(ii) a channel assignment operation; and
(f) a global timer to record times when the rows of pixels are sampled.

26. A method for capturing HDR images using an image sensor system comprising a pixel array, the method comprising:
(a) globally resetting the pixel array and initiating an exposure to snapshot an imaging scene;
(b) generating electrical signals from incident light with the pixel array in a plurality of row lines and column lines at the same time;
(c) immediately after the exposure begins, starting a row-wise scanning operation and selecting rows of pixel elements sequentially from the top of the pixel array;
(d) when a row is selected, determining, by a column-parallel voltage check operation, whether the pixel voltages in the row can be readout;
(e) assigning, in a channel assignment operation, the row of pixels to a readout channel for readout;
(f) immediately on completion of the channel assignment operation, continuing row-wise scanning, selecting the next row and repeating step (d);
(g) when the last row is scanned, checked and assigned according to steps (d) and (e), finishing a round of row-wise scanning and commencing a subsequent round of row-wise scanning by repeating step (c); and
(h) stopping the scanning when the time exceeds the exposure limit at the end of a scanning round, thereby finishing capture of the imaging scene.
